(19) United States
(12) Patent Application Publication
(10) Pub. No.: US 2009/0101912 A1
(43) Pub. Date: Apr. 23, 2009

(54) ACTIVE DEVICE ARRAY FOR REDUCING DELAY OF SCAN SIGNAL AND FLAT PANEL DISPLAY USING THE SAME

(75) Inventor: Shu-Yang Lin, Yunlin County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: Chunghwa Picture Tubes, LTD., Taipei (TW)

(21) Appl. No.: 12/183,073

(22) Filed: Jul. 31, 2008

(30) Foreign Application Priority Data
Oct. 23, 2007 (TW) 96139700

(51) Int. Cl. H01L 33/00

(52) U.S. Cl. 257/71; 257/E33.001

(57) ABSTRACT

An active device array and flat panel display using the same are provided. The active device array includes a plurality of pixels, a plurality of scan-lines, a plurality of data-lines and a plurality of auxiliary scan-lines, wherein each pixel is electrically connected to a corresponding scan-line and a corresponding data-line. Each scan-line has a first terminal and a second terminal, and the first terminal of scan-line receives a scan signal. The auxiliary scan-lines correspond to the scan-lines. One terminal of each auxiliary scan-line is electrically connected to the first terminal of a corresponding scan-line, and the other terminal thereof is electrically connected to the second terminal of the corresponding scan-line.

### CROSS-REFERENCE TO RELATED APPLICATION

This application claims the priority benefit of Taiwan application serial no. 96139700, filed on Oct. 23, 2007. The entirety of the above-mentioned patent application is hereby incorporated by reference herein and made a part of this specification.

### BACKGROUND OF THE INVENTION

1. Field of the Invention

The present invention relates to a flat panel display. More particularly, the present invention relates to an active device array and a flat panel display using the same.

2. Description of Related Art

In recent years, with a great development of image display techniques, the conventional cathode ray tube (CRT) displays are gradually substituted by flat panel displays. A commonly used flat panel display is a thin-film transistor liquid crystal display (TFT-LCD), the TFT-LCD becomes popular in the market due to its advantages of low power consumption, slim shape and high resolution etc.

FIG. 1 is a structural diagram of a conventional LCD 100. Referring to FIG. 1, the LCD 100 includes a display panel 110, a gate driver 120 and a source driver 130. The gate driver 120 and the source driver 130 respectively have N driving terminals and M transmitting terminals, and are electrically connected to the display panel 110 through the driving terminals and the transmitting terminals. The display panel 110 includes N scan lines SL₁˜SL_{N}, M data lines DL₁˜DL_{M} and M*N pixels U₁₁˜U_{MN}, wherein each pixel is electrically connected to the corresponding scan line and the corresponding data line.

Referring to FIG. 1 again, the N driving terminals of the gate driver 120 of the LCD 100 are electrically connected to the corresponding scan lines SL₁˜SL_{N}, and sequentially output a scan signal for each scan line to enable the pixels U₁₁˜U_{MN} on the corresponding scan lines SL₁˜SL_{N}. However, during enable of the pixels by the gate driver 120, a waveform of the scan signal is changed due to a delay effect caused by parasitic resistances and parasitic capacitances on the scan line.

FIG. 2A is an equivalent circuit diagram of a scan line having parasitic resistances and parasitic capacitances. FIG. 2B is a diagram illustrating a waveform variation of a signal transmitted by the scan line of FIG. 2A. Referring to FIG. 2A and FIG. 2B, a signal SC is input from a terminal A of the scan line, and the signal SC is measured on a terminal B. A waveform variation of the signal SC is shown in FIG. 2B. Therefore, according to FIG. 2A and FIG. 2B, when the scan line has to be elongated according to a design requirement, the parasitic resistances and parasitic capacitances on the scan line are increased, and the signal delay will be more obvious (only after a delay time, may a voltage increased from a level V1 to a level V2). Namely, as to a large size LCD, since the scan lines are quite long, signal delay of the large size LCD will be more severe than that of a small size LCD, and accordingly the rear pixels cannot be duly enabled for receiving data signals. Therefore, display quality is reduced due to insufficient charging of the pixels.

Accordingly, to solve the above problem of the conventional LCD 100, a technique of bi-directional driving circuit for driving the pixels is provided. FIG. 3 is structural diagram of a LCD 300 applying a bi-directional gate driver. Referring to FIG. 3, the LCD 300 includes a display panel 110, two gate drivers 320 and 321, and a source driver 330. The LCD 300 is similar to that of the conventional LCD. 100, the difference there between is that the display panel 110 is disposed between the two gate drivers 320 and 321 for simultaneously receiving the scan signals from the two gate drivers 320 and 321.

This technique may solve the delay effect caused by the parasitic resistances and the parasitic capacitances on the scan lines, the gate driver 320 and 321 may simultaneously transmit the scan signals for simultaneously driving the pixels on the scan lines. Therefore, the gate driver 320 is only responsible for driving a half of the pixels on the scan lines, and the gate driver 321 is responsible for driving another half of the pixels. In other words, on a scan line, the number of pixels required to be driven by one of the gate drivers drops from the original M pixels to M/2 pixels, such that affection of the delay effect is reduced to a half. Similarly, operation of another one of the gate drivers is the same, and therefore affection of the delay effect may be effectively reduced.

It should be noted that though such technique may effectively reduce the affection of the delay effect, it may still cause other problems. For example, an issue of synchronous output has to be taken into consideration. Since the two gate drivers are required to simultaneously output the scan signals, if the scan signals are output asynchronously, two ends of the scan line may have a potential difference. Namely, when one end of the scan line has a high voltage level, and another end of the scan line has a low voltage level, a current is generated on the scan line, which may cause an additional power consumption. Moreover, compared to the conventional LCD 100, the LCD 300 requires double gate drivers, and the gate driver is expensive, and therefore fabrication cost is increased accordingly.

### SUMMARY OF THE INVENTION

The present invention is directed to an active device array, which may solve waveform variation caused by parasitic resistances and parasitic capacitances on scan lines, while the pixels of a display panel are enabled.

The present invention is directed to a flat panel display, by which additional power consumption and fabrication cost due to application of a conventional bi-directional driving method may be avoided.

Based on the aforementioned and other objectives, the present invention provides an active device array including a plurality of pixels, a plurality of scan-lines, a plurality of data-lines and a plurality of auxiliary scan-lines, wherein each pixel is electrically connected to a corresponding scan-line and a corresponding data-line. Each scan-line has a first terminal and a second terminal, and the first terminal of the scan-line receives a scan signal. The auxiliary scan-lines correspond to the scan-lines. One terminal of each auxiliary scan-line is electrically connected to the first terminal of the corresponding scan-line, and the other terminal thereof is electrically connected to the second terminal of the corresponding scan-line.

According to another aspect of the present invention, a flat panel display including a gate driver, a plurality of pixels, a plurality of scan-lines, a plurality of data-lines and a plurality of auxiliary scan-lines is provided, wherein each pixel is electrically connected to a corresponding scan-line and a corresponding data-line. The gate driver includes a plurality of driving terminals, and each driving terminal is suitable for outputting a scan signal. Each scan-line has a first terminal and a second terminal, and the first terminal of the scan-line receives a scan signal. The auxiliary scan-lines correspond to the scan-lines. One terminal of each auxiliary scan-line is electrically connected to the first terminal of the corresponding scan-line, and the other terminal thereof is electrically connected to the second terminal of the corresponding scan-line.

In an embodiment of the present invention, a number of the pixels is M×N, and a number of the scan lines is N, wherein each scan line is electrically connected to M pixels, and M and N are natural numbers.

In an embodiment of the present invention, each of the pixels includes a thin-film transistor and a pixel capacitor. Wherein, the thin-film transistor is electrically connected to the corresponding scan line and the corresponding data line. One terminal of the pixel capacitor is electrically connected to the thin-film transistor, and the other terminal thereof is electrically connected to a common level.

In an embodiment of the present invention, a (i×j)-th pixel is electrically connected to an i-th data line and a j-th scan line.

In an embodiment of the present invention, one terminal of a j-th auxiliary scan line is electrically connected to a (1×j)-th pixel, and the other terminal thereof is electrically connected to a (M×j)-th pixel.

In the embodiment of the present invention, a plurality of auxiliary scan lines is applied for simultaneously inputting scan signals to two terminals of the scan lines. Therefore, waveform variation caused by parasitic resistances and parasitic capacitances on the scan lines may be mitigated. Moreover, applying the plurality of auxiliary scan lines may achieve the same function as that of a conventional bi-directional driving method, and therefore additional power consumption may be avoided, and fabrication cost may be reduced.

In order to make the aforementioned and other objects, features and advantages of the present invention comprehensible, a preferred embodiment accompanied with figures is described in detail below.

### BRIEF DESCRIPTION OF THE DRAWINGS

FIG. 1 is a structural diagram of a conventional LCD 100.

FIG. 2A is an equivalent circuit diagram of a scan line having parasitic resistances and parasitic capacitances.

FIG. 2B is a diagram illustrating a waveform variation of a signal transmitted by the scan line of FIG. 2A.

FIG. 3 is structural diagram of a LCD 300 applying a bi-directional gate driver.

FIG. 4 is a schematic diagram illustrating an active device array 400 according an embodiment of the present invention.

FIG. 5 is a circuit diagram illustrating a flat panel display 500 according to another embodiment of the present invention.

FIG. 6A is a diagram illustrating a signal waveform of the scan line SL₁ of the conventional LCD 100 of FIG. 1.

FIG. 6B is a diagram illustrating a signal waveform of the scan line SL₁ of the flat panel display 500 of FIG. 5.

### DESCRIPTION OF EMBODIMENTS

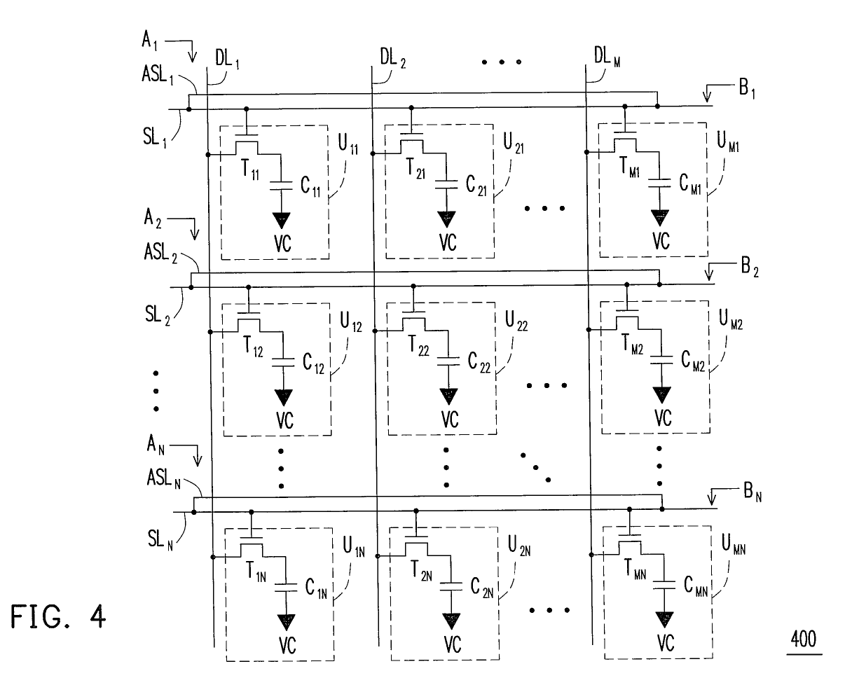

FIG. 4 is a schematic diagram illustrating an active device array 400 according an embodiment of the present invention. Referring to FIG. 4, the active device array 400 includes M*N pixels (wherein M and N are natural numbers) U₁₁˜U_{MN}, N scan lines SL₁˜SL_{N}, N auxiliary scan lines ASL₁˜ASL_{N} and M data lines DL₁˜DL_{M}. Wherein, the pixels U₁₁˜U_{MN} are electrically connected to the corresponding scan lines SL₁˜SL_{N} and the corresponding data lines DL₁˜DL_{M}, respectively. For example, a (i×j)-th pixel (i.e. a pixel Uᵢⱼ, wherein 1≦i≦M, 1≦j≦N, and i, j are natural numbers) is electrically connected to a corresponding i-th data line (data line DLᵢ) and a corresponding j-th scan line (scan line SLⱼ). The scan-lines SL₁˜SL_{N} respectively have first terminals A₁˜A_{N}, and second terminals B₁˜B_{N}. Two terminals of the auxiliary scan lines ASL₁˜ASL_{N} are electrically connected to the first terminals A₁˜A_{N} and the second terminals B₁˜B_{N} of the corresponding scan lines SL₁˜SL_{N}, respectively. Namely, one terminal of a j-th auxiliary scan-line ASLⱼ is electrically connected to a first terminal Aⱼ of a corresponding j-th scan-line SLⱼ, and the other terminal of the j-th auxiliary scan-line ASLⱼ is electrically connected to a second terminal Bⱼ of the corresponding j-th scan-line SLⱼ.

In the present embodiment, the pixels U₁₁˜U_{MN} includes thin film transistors T₁₁˜T_{MN} and pixel capacitors C₁₁˜C_{MN}, wherein gates of the thin film transistors T₁₁˜T_{MN} are electrically connected to the corresponding scan lines, and sources thereof are electrically connected to the corresponding data lines, respectively. For example, as to a thin film transistor Tᵢⱼ within the pixel Uᵢⱼ, the gate thereof is electrically connected to the j-th scan line, and the source thereof is electrically connected to the i-th data line; as to a pixel capacitor Cᵢⱼ within the pixel Uᵢⱼ, one terminal thereof is electrically connected to a drain of the thin film transistor Tᵢⱼ, the other terminal thereof is electrically connected to a common level VC. Therefore, corresponding liquid crystal molecules may be driven by pixel electrodes (not shown) electrically connected to the drains of the transistors T₁₁˜T_{MN}.

In addition, one terminal of the J-th auxiliary scan line (the scan line ASLⱼ) is electrically connected to the gate of a thin film transistor T₁ⱼ of a (1×j)-th pixel (pixel U₁ⱼ), and the other terminal thereof is electrically connected to the gate of a thin film transistor T_{Mj} of a (M×j)-th pixel (pixel U_{Mj}).

Referring to FIG. 4 again, a first scan line (scan line SL₁) is taken as an example for explaining the scope of the present invention. When a scan signal is input from a first terminal A₁ of the scan line SL₁, the scan signal may drive the pixels U₁₁-U_{M1} via the scan line SL₁. Moreover, the scan signal may be input from a second terminal B₁ of the scan line SL₁ via an electrically connected auxiliary scan line ASL₁, so as to drive the pixels U₁₁˜U_{M1}. In other words, due to the parallel connection between the scan line SL₁ and the auxiliary scan line ASL₁, the scan signal may be simultaneously input from the first terminal A₁ and the second terminal B₁ of the scan line SL₁ for driving the pixels U₁₁˜U_{M1}. Therefore, only a half of the pixels on the scan lines SL₁ are required to be driven by the scan signal input from each of the two terminals of the scan line SL₁, and rear pixels on the scan line SL₁ (i.e. pixels close to the second terminal B₁ of the scan line SL₁) may be duly enabled for receiving the data signal. Thus, the same function as that of a conventional bi-directional driving method may be achieved without using the conventional bi-directional driving method.

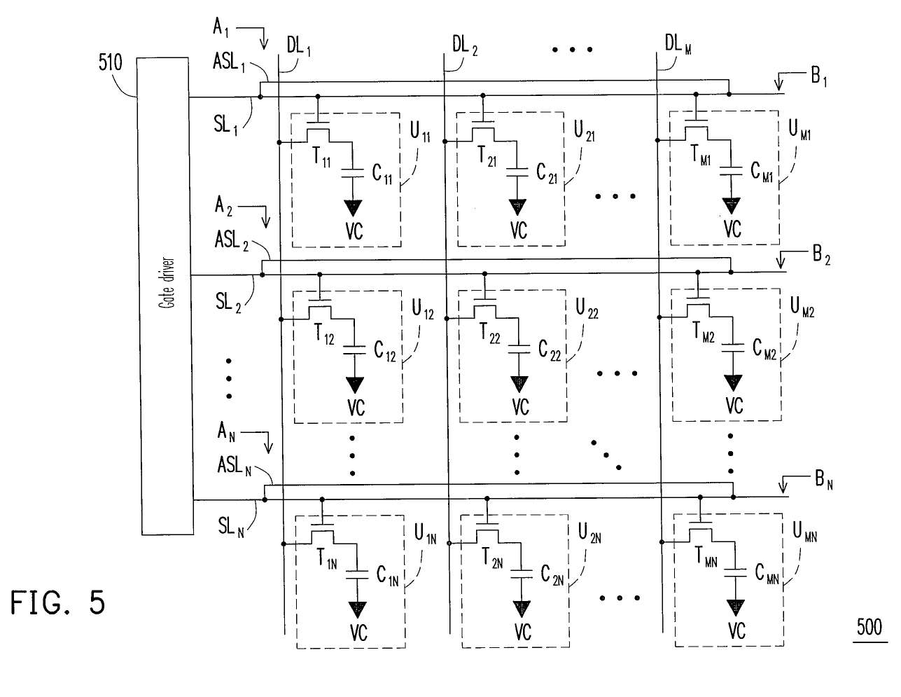

FIG. 5 is a circuit diagram illustrating a flat panel display 500 according to another embodiment of the present invention. Referring to FIG. 5, the flat panel display 500 includes a gate driver 510, M*N pixels (wherein M and N are natural numbers) U₁₁˜U_{MN}, N scan lines SL₁˜SL_{N}, N auxiliary scan lines ASL₁˜ASL_{N} and M data lines DL₁˜DL_{M}. Wherein, the pixels U₁₁˜U_{MN} are electrically connected to the corresponding scan lines SL₁˜SL_{N} and the corresponding data lines DL₁˜DL_{M}, respectively. The scan-lines SL₁˜SL_{N} respectively have first terminals A₁˜A_{N}, and second terminals B₁˜B_{N}. Two terminals of the auxiliary scan lines ASL₁˜ASL_{N} are electrically connected to the first terminals A₁˜A_{N} and the second terminals B₁˜B_{N} of the corresponding scan lines SL₁˜SL_{N}, respectively. Namely, one terminal of a j-th auxiliary scan-line ASLⱼ is electrically connected to a first terminal Aⱼ of a corresponding j-th scan-line SLⱼ, and the other terminal thereof is electrically connected to a second terminal Bⱼ of the corresponding j-th scan-line SLⱼ. The gate driver 510 includes N driving terminals, which are electrically connected to the first terminals A₁˜A_{N} of the corresponding scan lines SL₁˜SL_{N}, respectively.

In the present embodiment of the present invention, the pixels U₁₁˜U_{MN} includes thin film transistors T₁₁˜T_{MN} and pixel capacitors C₁₁˜C_{MN}, and a coupling method thereof is similar to that of the above embodiment, and therefore the detailed description thereof will not be repeated. In addition, one terminal of the j-th auxiliary scan line (auxiliary scan line ASLⱼ) is electrically connected to the gate of a thin film transistor T₁ⱼ of a (1×j)-th pixel (pixel U₁ⱼ), and the other terminal thereof is electrically connected to the gate of a thin film transistor T_{Mj} of a (M×j)-th pixel (pixel U_{Mj}).

Referring to FIG. 5 again, when the N driving terminals of the gate driver 510 respectively output the scan signals to the corresponding scan lines SL₁˜SL_{N}, the scan signals may drive the pixels U₁₁˜U_{M1} via the scan line SL₁˜SL_{N}. Moreover, the scan signals may be input from the second terminals B₁˜B_{N} of the scan lines SL₁˜SL_{N} via auxiliary scan lines ASL₁˜ASL_{N} electrically connected with the scan lines SL₁˜SL_{N} in parallel, so as to drive the pixels U₁₁˜U_{MN}. Therefore, similar to the above embodiment, only a half of the pixels are required to be driven by the scan signals input from each of the two terminals of the scan lines SL₁˜SL_{N}, and the rear pixels on the scan lines SL₁˜SL_{N} may be duly enabled for receiving the data signal. Thus, a same function as that of a conventional bi-directional driving method may be achieved without using the conventional bi-directional driving method.

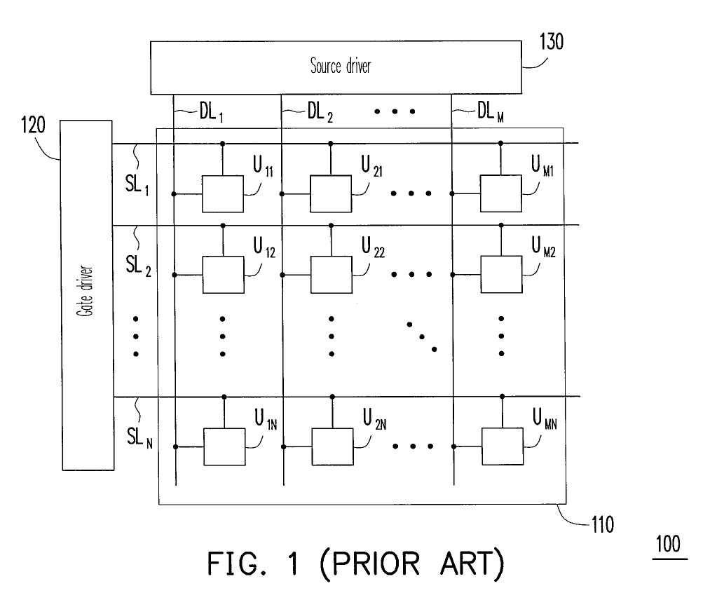

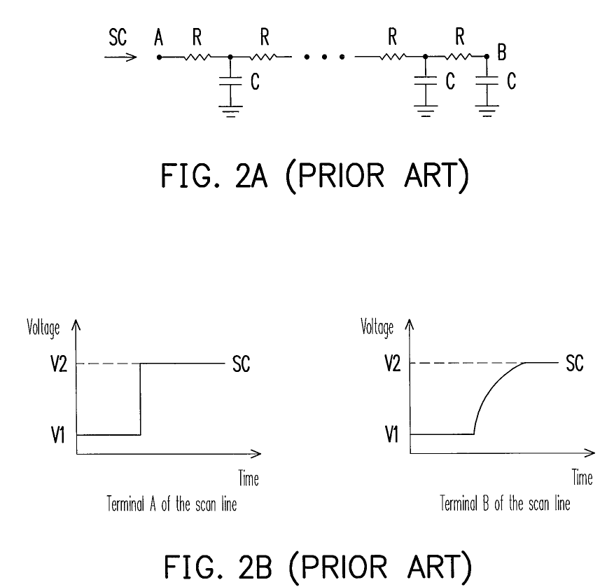

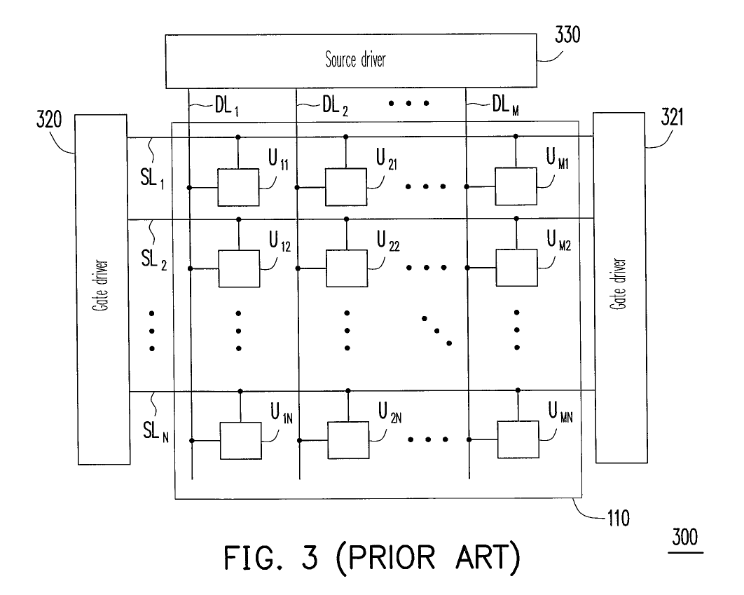

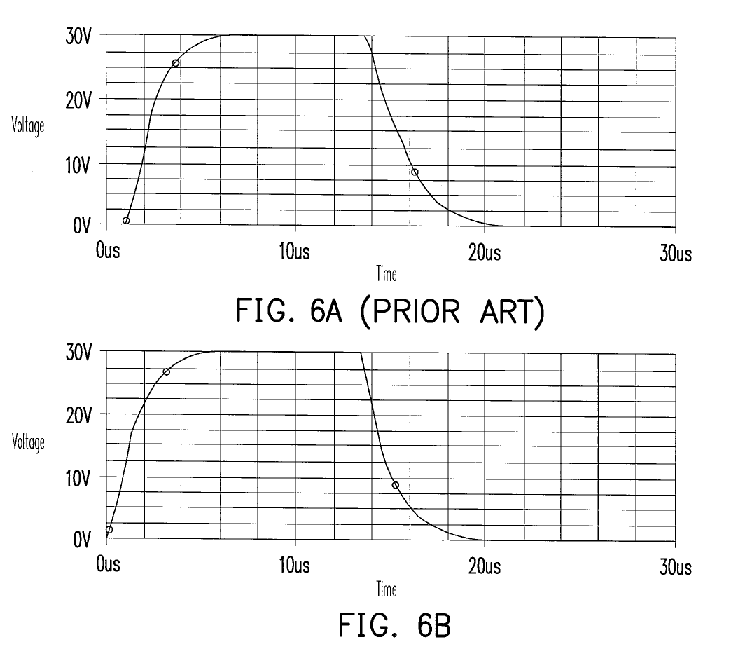

FIG. 6A is a diagram illustrating a signal waveform of the scan line SL₁ of the conventional LCD 100 of FIG. 1. FIG. 6B is a diagram illustrating a signal waveform of the scan line SL₁ of the flat panel display 500 of FIG. 5. Comparing FIG. 6A to FIG. 6B, the signal waveform of FIG. 6B is more close to an ideal waveform, which means a delay effect caused by parasitic resistances and parasitic capacitances on scan lines may be effectively mitigated.

In summary, according to the present invention, the scan lines are electrically connected to the auxiliary scan lines in parallel, such that the scan signals may be simultaneously input to the first terminals and the second terminals of the scan lines, and accordingly only a half of the pixels is required to be driven by the scan signal input from each terminal of the scan line. By such means, the delay effect caused by parasitic resistances and parasitic capacitances on scan lines may be effectively mitigated. Moreover, by connecting the scan lines with the auxiliary scan lines in parallel, the same function as that of a conventional bi-directional driving method may be achieved, and problems of additional power consumption and high fabrication cost occurred when applying the conventional bi-directional driving method may be solved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An active device array, comprising:
a plurality of pixels;
a plurality of scan lines and a plurality of data lines, electrically connected to the pixels, wherein each scan line includes a first terminal and a second terminal, and the first terminal of each scan line receives a scan signal; and
a plurality of auxiliary scan lines, respectively disposed corresponding to the scan-lines, wherein one terminal of each auxiliary scan-line is electrically connected to the first terminal of a corresponding scan-line, and the other terminal of each auxiliary scan-line is electrically connected to the second terminal of the corresponding scan-line.

2. The active device array as claimed in claim 1, wherein the pixels comprise M×N pixels, the scan lines comprise N scan lines, wherein each scan line is electrically connected to M pixels, where M and N are natural numbers.

3. The active device array as claimed in claim 2, wherein each pixel comprises:
a thin-film transistor, electrically connected to a corresponding scan line and a corresponding data line; and
a pixel capacitor, comprising one terminal electrically connected to the thin-film transistor, and another terminal electrically connected to a common level.

4. The active device array as claimed in claim 2, wherein a (i×j)-th pixel is electrically connected to an i-th data line and a j-th scan line.

5. The active device array as claimed in claim 4, wherein one terminal of a j-th auxiliary scan line is electrically connected to a (1×j)-th pixel, and the other terminal of the j-th auxiliary scan line is electrically connected to a (M×j)-th pixel.

6. A flat panel display, comprising:
at least a gate driver comprising a plurality of driving terminals for respectively outputting a scan signal;
a plurality of pixels;
a plurality of scan lines and a plurality of data lines, electrically connected to the pixels, wherein each scan line includes a first terminal and a second terminal, and the first terminal of each scan line is electrically connected to the driving terminal of the gate driver; and
a plurality of auxiliary scan lines, respectively disposed corresponding to the scan-lines, wherein one terminal of each auxiliary scan-line is electrically connected to the first terminal of a corresponding scan-line, and the other terminal of each auxiliary scan-line is electrically connected to the second terminal of the corresponding scan-line.

7. The flat panel display as claimed in claim 6, wherein the pixels comprise M×N pixels, the scan lines comprise N scan lines, wherein each scan line is electrically connected to M pixels, and wherein M and N are natural numbers.

8. The flat panel display as claimed in claim 7, wherein each pixel comprises:
a thin-film transistor, electrically connected to a corresponding scan line and a corresponding data line; and
a pixel capacitor, comprising one terminal electrically connected to the thin-film transistor, and another terminal electrically connected to a common level.

9. The flat panel display as claimed in claim 7, wherein a (i×j)-th pixel is electrically connected to an i-th data line and a j-th scan line.

10. The flat panel display as claimed in claim 9, wherein one terminal of a j-th auxiliary scan line is electrically connected to a (1×j)-th pixel, and another terminal of the j-th auxiliary scan line is electrically connected to a (M×j)-th pixel.
